(19) United States
(12) Patent Application Publication
(10) Pub. No.: US 2025/0337270 A1
(43) Pub. Date: Oct. 30, 2025

(54) DETECTION METHOD, CONTROL DEVICE, POWER DISTRIBUTION BOX, AND STORAGE MEDIUM

(71) Applicant: SHENZHEN HELLO TECH ENERGY CO., LTD, Shenzhen (CN)

(72) Inventors: Shaohong DAI, Shenzhen (CN); Zhongwei SUN, Shenzhen (CN); Riyi YE, Shenzhen (CN)

(21) Appl. No.: 19/264,883

(22) Filed: Jul. 10, 2025

Related U.S. Application Data
(63) Continuation of application No. PCT/CN2025/095492, filed on May 16, 2025.

(30) Foreign Application Priority Data
Oct. 9, 2024 (CN) 202411417028.5

(51) Int. Cl. H02J 9/06; G01R 19/10; G01R 19/175; H02J 3/00

(52) U.S. Cl. CPC H02J 9/062; G01R 19/10; G01R 19/175; H02J 3/001

(57) ABSTRACT

Provided are a detection method, a control device, a power distribution box, and a storage medium. The detection method applied in a power distribution box includes: obtaining a real-time input alternating-current voltage and a zero-point alternating-current phase of the power distribution box within a utility power cycle; obtaining a simulated input alternating-current voltage of the power distribution box within the utility power cycle based on the zero-point alternating-current phase; determining that the real-time input alternating-current voltage is normal in response to an alternating-current voltage difference between the simulated input alternating-current voltage and the real-time input alternating-current voltage being smaller than or equal to a predetermined threshold, or determining that the real-time input alternating-current voltage is abnormal in response to the alternating-current voltage difference between the simulated input alternating-current voltage and the real-time input alternating-current voltage being greater than the predetermined threshold.

### CROSS-REFERENCE TO RELATED APPLICATION

This application is a continuation of International Patent Application No. PCT/CN2025/095492, filed on May 16, 2025, which claims priority to and the benefit of Chinese Patent Application No. 202411417028.5, filed with China National Intellectual Property Administration on Oct. 9, 2024, both of which are incorporated herein by reference in their entireties.

### FIELD

The present disclosure relates to the technical field of power distribution boxes, and in particular, to a detection method, a first control device, a second control device, a power distribution box, and a non-volatile computer-readable storage medium.

### BACKGROUND

At present, a portable energy storage power supply may be connected to a utility power supply by a user using a portable power distribution box to provide a user load with an uninterruptible power supply. Typically, a time for operation of switching between an alternating current power supply supplied by the portable energy storage power supply and an alternating current power supply supplied by the utility power supply does not exceed a predetermined value (such as 20 milliseconds). However, the inventor has realized that a standard switching action of a general relay or circuit breaker will take a predetermined amount of time. Therefore, a detection time for determining whether to switch the power supply cannot be too long, otherwise it will affect a switching speed and fail to satisfy design requirements.

### SUMMARY

Embodiments of the present disclosure provide a detection method, a first control device, a second control device, a power distribution box, and a non-volatile computer-readable storage medium to solve a problem that a switching speed of the power distribution box when switching between an energy storage power supply and a utility power supply fails to satisfy design requirements.

In the embodiments of the present disclosure, a detection method applied in a power distribution box is provided. The detection method includes: obtaining a real-time input alternating-current voltage and a zero-point alternating-current phase of the power distribution box within a utility power cycle; obtaining a simulated input alternating-current voltage of the power distribution box within the utility power cycle based on the zero-point alternating-current phase; and determining that the real-time input alternating-current voltage is normal in response to an alternating-current voltage difference between the simulated input alternating-current voltage and the real-time input alternating-current voltage being smaller than or equal to a predetermined threshold, or determining that the real-time input alternating-current voltage is abnormal in response to the alternating-current voltage difference between the simulated input alternating-current voltage and the real-time input alternating-current voltage being greater than the predetermined threshold.

In the above embodiments, by detecting the alternating-current voltage difference between the real-time input alternating-current voltage and the simulated input alternating-current voltage within the utility power cycle to determine whether the real-time input alternating-current voltage of the power distribution box is normal, interference from an X capacitor disposed between a neutral wire and a live wire in the prior art can be reduced, which can improve the switching speed to some extent.

In the embodiments of the present disclosure, a first control device for a power distribution box is provided. The first control device includes a first obtaining module, a second obtaining module, a first determination module, and a second determination module. The first obtaining module is configured to obtain a real-time input alternating-current voltage and a zero-point alternating-current phase of the power distribution box within a utility power cycle. The second obtaining module is configured to obtain a simulated input alternating-current voltage of the power distribution box within the utility power cycle based on the zero-point alternating-current phase. The first determination module is configured to determine that the real-time input alternating-current voltage is normal in response to an alternating-current voltage difference between the simulated input alternating-current voltage and the real-time input alternating-current voltage being smaller than or equal to a predetermined threshold. The second determination module is configured to determine that the real-time input alternating-current voltage is abnormal in response to the alternating-current voltage difference between the simulated input alternating-current voltage and the real-time input alternating-current voltage being greater than the predetermined threshold.

In the embodiments of the present disclosure, a second control device is provided. The second control device includes a processor, a memory, and a computer program. The computer program is stored in the memory and executed by the processor. The computer program includes an instruction configured to execute the detection method described in the above embodiments.

In the embodiments of the present disclosure, a power distribution box is provided. The power distribution box includes a control device. The control device is the first control device or the second control device described above.

In the embodiments of the present disclosure, a non-volatile computer-readable storage medium is provided. The non-volatile computer-readable storage medium includes a computer program. The computer program, when executed by a processor, causes the processor to execute the detection method described above.

Additional aspects and advantages of the embodiments of the present disclosure will be provided in part in the following description, or will become apparent in part from the following description, or can be learned from practicing of the embodiments of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings, in which:

FIG. 1 is a schematic diagram of a scene of a detection method according to some embodiments of the present disclosure;

FIG. 2 is a schematic structural diagram of a power distribution box according to some embodiments of the present disclosure;

FIG. 3 to FIG. 6 are schematic flowcharts of a detection method according to some embodiments of the present disclosure;

FIG. 7 is a schematic structural diagram of a power distribution box according to some embodiments of the present disclosure;

FIG. 8 and FIG. 9 are schematic flowcharts of a detection method according to some embodiments of the present disclosure;

FIG. 10 is a schematic diagram of a scene of a detection method according to some embodiments of the present disclosure;

FIG. 11 is a schematic diagram of a module of a first control device according to some embodiments of the present disclosure;

FIG. 12 is a schematic structural diagram of a second control device according to some embodiments of the present disclosure; and

FIG. 13 is a schematic diagram of a connection state of a non-volatile computer-readable storage medium and a processor according to some embodiments of the present disclosure.

### DESCRIPTION OF REFERENCE NUMERALS

100, power distribution box; 10, first control device; 11, first obtaining module; 12, second obtaining module; 13, first determination module; 14, second determination module; 15, control module; 16, calculation module; 20, second control device; 21, processor; 22, memory; 221, computer program; 30, load interface; 40, first interface; 50, second interface; 60, switching switch; 72, isolated operational amplifier circuit; 74, isolated optocoupler; 80, control unit; 92, first metering circuit; 94, second metering circuit; 96, third metering circuit; 961, phase sampling module; 200, non-volatile computer-readable storage medium.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the accompanying drawings are optional only, and are intended to explain, rather than limiting, the embodiments of the present disclosure.

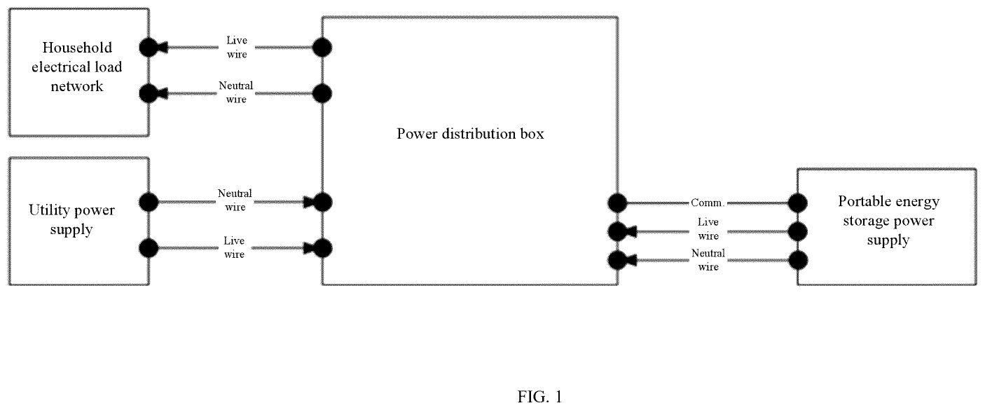

At present, as shown in FIG. 1, a user needs to use a power distribution box for operation when switching is performed between an alternating-current power supply supplied by a portable energy storage power supply and an alternating-current power supply supplied by utility power, while needing to satisfy that an alternating-current switching time does not exceed milliseconds. However, a standard switching action time of a general relay or circuit breaker is approximately 15 milliseconds. Therefore, a detection time for an alternating-current power failure needs to be controlled within no more than 5 milliseconds.

In the related art, a detection method for the alternating-current power failure includes performing signal triggering based on an isolated pulse or a level signal to perform power failure detection, and another detection method for the alternating-current power failure includes converting an alternating-current voltage into an isolated analog voltage according to a ratio for performing sampling determination to perform the power failure detection. However, the alternating current by both methods is affected by the X capacitors (that are elements configured to suppress electromagnetic interference and are connected in parallel between a live wire and a neutral wire of the alternating-current power supply) of the neutral wire and the live wire, resulting in a time for determining whether a power failure occurs being greater than milliseconds, which fails to satisfy design requirements and thus cannot quickly determine whether the power failure occurs in the alternating-current.

To solve the above technical problem, the embodiments of the present disclosure provide a detection method.

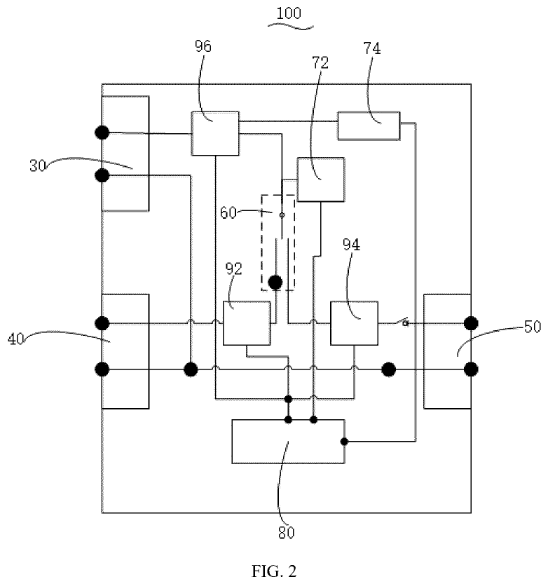

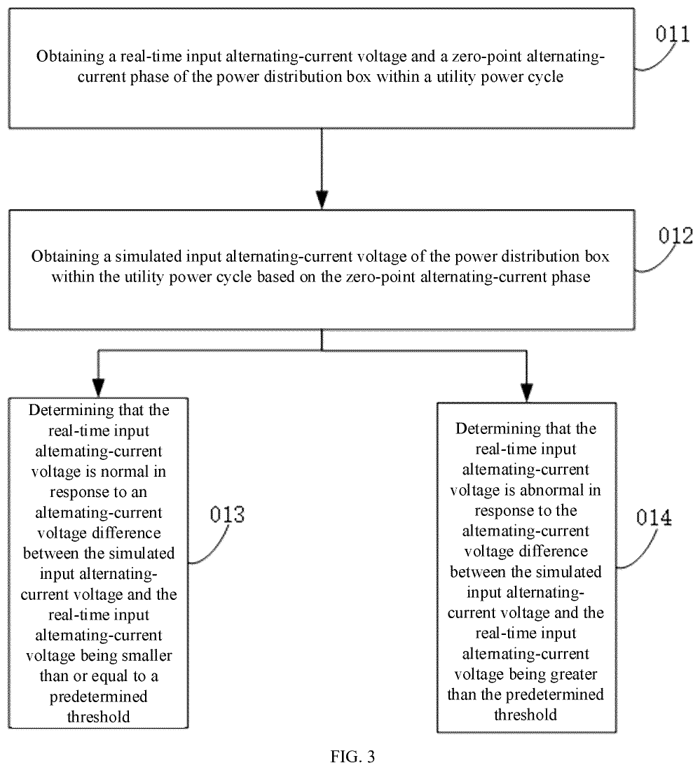

Referring to FIG. 2 and FIG. 3, the embodiments of the present disclosure provide a detection method applied in a power distribution box 100. The detection method includes operations at blocks 011 to 014.

At block 011, a real-time input alternating-current voltage and a zero-point alternating-current phase of the power distribution box 100 are obtained within a utility power cycle.

At block 012, a simulated input alternating-current voltage of the power distribution box 100 within the utility power cycle is obtained based on the zero-point alternating-current phase.

At block 013, it is determined that the real-time input alternating-current voltage is normal in response to an alternating-current voltage difference between the simulated input alternating-current voltage and the real-time input alternating-current voltage being smaller than or equal to a predetermined threshold.

At block 014, it is determined that the real-time input alternating-current voltage is abnormal in response to the alternating-current voltage difference between the simulated input alternating-current voltage and the real-time input alternating-current voltage being greater than the predetermined threshold.

In this way, by detecting the alternating-current voltage difference between the real-time input alternating-current voltage and the simulated input alternating-current voltage within the utility power cycle to determine whether the real-time input alternating-current voltage of the power distribution box 100 is normal, interference from an X capacitor disposed between the neutral wire and the live wire in the prior art can be reduced, which can improve a switching speed to some extent.

The power distribution box 100 is a device used for centralized protection, connection, control, and distribution of electrical power, and is usable for power distribution and control of an electrical equipment in an electrical power system. For example, a main power supply, a branch power supply, and a backup power supply may be connected to an electrical load by the power distribution box 100. The main power supply, the branch power supply, or the backup power supply is capable of supplying power to the electrical load. In response to one of the main power supply, the branch power supply, and the backup power supply that are connected to the load is out of power, the power distribution box 100 may switch to another power supply, to complete normal power transmission and distribution, providing stable and safe power to a device connected to the power distribution box 100 and a power utilization terminal.

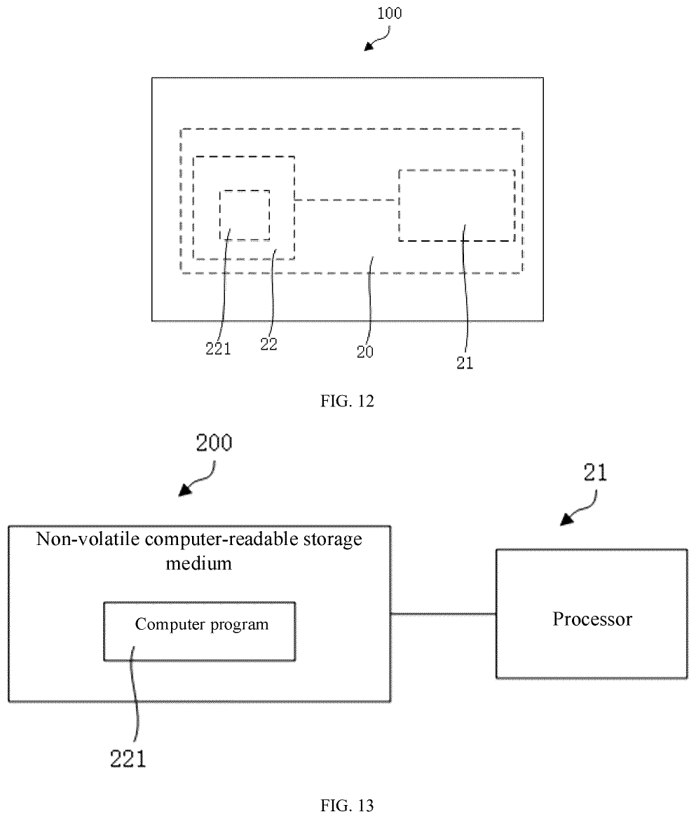

The power distribution box 100 includes a second control device 20. As shown in FIG. 12, the second control device 20 includes a processor 21 and a memory 22. The processor 21 may be a microcontroller unit (MCU) 80. The memory 22 is capable of storing a computer program 221 including an instruction for executing the detection method. The processor 21 is capable of executing the computer program 221 including the instruction for executing the detection method.

In some embodiments, before the power distribution box 100 performs power supply switching, it is necessary to detect whether a power failure situation occurs in the load and whether the real-time input alternating-current voltage in the power distribution box 100 is normal. Therefore, within a utility power cycle, the processor 21 can obtain the real-time input alternating-current voltage and the zero-point alternating-current phase of the power distribution box 100. The utility power cycle refers to a time required for an alternation current to complete a periodic change. For example, the frequency of a utility power supply is 50 Hz, which means that it changes 50 times per second, so the utility power cycle is 0.02 seconds.

The zero-point alternating-current phase is a change state of a sinusoidal alternating current at the start of timing, also known as an initial phase, is capable of reflecting a starting point of alternating current alternation, and is related to selection of a time starting point. The zero-point alternating-current phase represents a position of the sinusoidal alternating current at a specific moment, i.e., a specific point in a sine-wave waveform cycle, and is capable of determining an instantaneous value and a direction of the sinusoidal alternating current at a predetermined moment, as well as a change trend of the sinusoidal alternating current.

After obtaining the zero-point alternating-current phase, the processor 21 is capable of simulating a simulated input alternating-current voltage corresponding to the real-time input alternating-current voltage within one utility power cycle based on the zero-point alternating-current phase. The simulated input alternating-current voltage is a theoretical value of an input alternating-current voltage supplied to the power distribution box 100 by a power supply undisturbed by an environmental factor.

Based on the obtained real-time input alternating-current voltage and the simulated input alternating-current voltage, the processor 21 is capable of calculating the alternating-current voltage difference between the obtained real-time input alternating-current voltage and the simulated input alternating-current voltage, comparing the obtained alternating-current voltage difference with a predetermined threshold preset in the processor 21, and determining, based on the comparison result, whether the real-time input alternating-current voltage is normal, i.e., whether the power supply connected to the load supplies power to the load normally.

In response to the alternating-current voltage difference between the simulated input alternating-current voltage and the real-time input alternating-current voltage being smaller than or equal to the predetermined threshold (that may be 5V, 10V, 20V, or the like, and may be adjusted according to an actual test condition to prevent false triggering), i.e., a difference between an actual input alternating-current voltage and a calculated theoretical input alternating-current voltage being small, the processor 21 is capable of determining that the real-time input alternating-current voltage is normal.

In response to the alternating-current voltage difference between the simulated input alternating-current voltage and the real-time input alternating-current voltage being greater than the predetermined threshold, i.e., the difference between the actual input alternating-current voltage and the calculated theoretical input alternating-current voltage being large, the processor 21 is capable of determining that the real-time input alternating-current voltage is abnormal. At this time, the processor 21 is capable of controlling the power distribution box 100 to perform power supply switching.

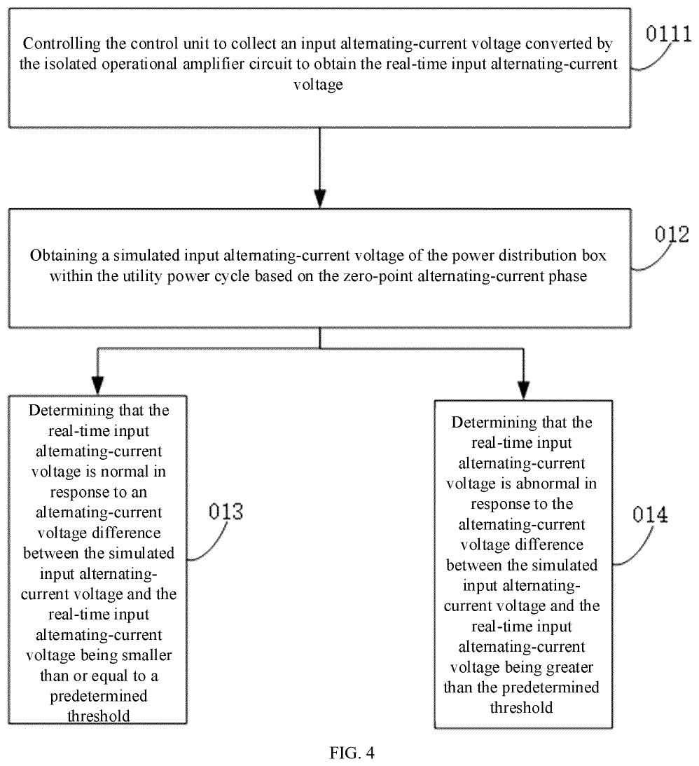

Referring to FIG. 2 and FIG. 4, in some embodiments, the power distribution box 100 includes a load interface 30, a first interface 40, a second interface 50, a switching switch 60, an isolated operational amplifier circuit 72, and a control unit 80. The switching switch 60 is configured to switch connections between the load interface 30 and the first interface 40 and between the load interface 30 and the second interface 50. The isolated operational amplifier circuit 72 is disposed between the load interface 30 and the switching switch 60 and electrically connected to the control unit 80. The operation at block 011 of obtaining the real-time input alternating-current voltage of the power distribution box 100 includes an operation at block 0111.

At block 0111, the control unit 80 is controlled to collect an input alternating-current voltage converted by the isolated operational amplifier circuit 72 to obtain the real-time input alternating-current voltage.

In this way, by providing the isolated operational amplifier circuit 72 in the power distribution box 100, the input alternating-current voltage can be converted by the isolated operational amplifier circuit 72 and then collected by the control unit 80, enabling the control unit 80 to obtain the real-time input alternating-current voltage.

In some embodiments, the power distribution box 100 includes a load interface 30, a first interface 40, a second interface 50, a switching switch 60, an isolated operational amplifier circuit 72, and a control unit 80. The load interface 30 may be a wiring terminal or an insertion hole configured to be connected to a load device, and thus is capable of allowing the load device to be connected to the power distribution box 100 via an electrical wire or an electrical cable to receive power for operation. The load interface 30 has different forms such as a socket-type interface, a wiring terminal block, and a bus duct according to different types of load devices and wiring manner requirements.

The first interface 40 and the second interface 50 may be power interfaces of the power distribution box 100, and may be wiring terminals, insertion holes, or busbars configured to be connected to an external power cord. For example, the first interface 40 is capable of being connected to the utility power supply, and the second interface 50 is capable of being connected to the portable energy storage power supply. The first interface 40 and the second interface 50 have various types. For example, the first interface 40 and the second interface 50 may be plug-in interfaces, bolt-fixed interfaces, or bus interfaces. The plug-in interface is suitable for a low-current and low-voltage scene. The bolt-fixed interface is suitable for a high-current and high-voltage scene. The bus interface is typically used in a power distribution system with a high capacity and high reliability.

The switching switch 60 may be a relay or circuit breaker, and is capable of performing switching between a plurality of power supplies connected to the power distribution box 100 to select a power supply capable of supplying power to the load. For example, when the utility power supply being connected to the first interface 40 and the portable energy storage power supply being connected to the second interface 50, in response to the portable energy storage power supply cannot supply power to the load, the switching switch 60 may switch the second interface 50 to the first interface 40, and the first interface 40 is connected to the load, allowing the utility power supply to supply power to the load.

The isolated operational amplifier circuit 72 is a special measurement amplifier circuit configured to condition, isolate, and convert various signals into standard signals acceptable to the control unit 80 or special signals specified by the user. For example, the isolated operational amplifier circuit 72 is capable of converting the real-time input alternating-current voltage into a voltage signal that is within a sampling range of the control unit 80 and allows the control unit 80 to perform normal sampling. Moreover, the isolated operational amplifier circuit 72 is capable of avoiding interference from a loop current to ensure signal accuracy. The isolated operational amplifier circuit 72 is electrically insulated from an input circuit and an output circuit without direct electrical coupling to the input circuit and the output circuit, i.e., there is no common ground terminal during signal transmission, enabling the isolated operational amplifier circuit 72 to transmit signals with a high impedance and high common-mode rejection capability in a noisy environment.

The control unit 80 may include a processor 21, such as a micro controller unit (MCU) 80, which may process various collected data and control and execute instructions. The control unit 80 is capable of collecting the input alternating-current voltage converted by the isolated operational amplifier circuit 72 to obtain the real-time input alternating-current voltage of the power distribution box 100.

In an embodiment, the control unit 80 may include the second control device 20.

In an embodiment, the control unit 80 may be in a communication connection with the second control device 20, and the second control device 20 may implement corresponding operations at blocks by controlling the control unit 80.

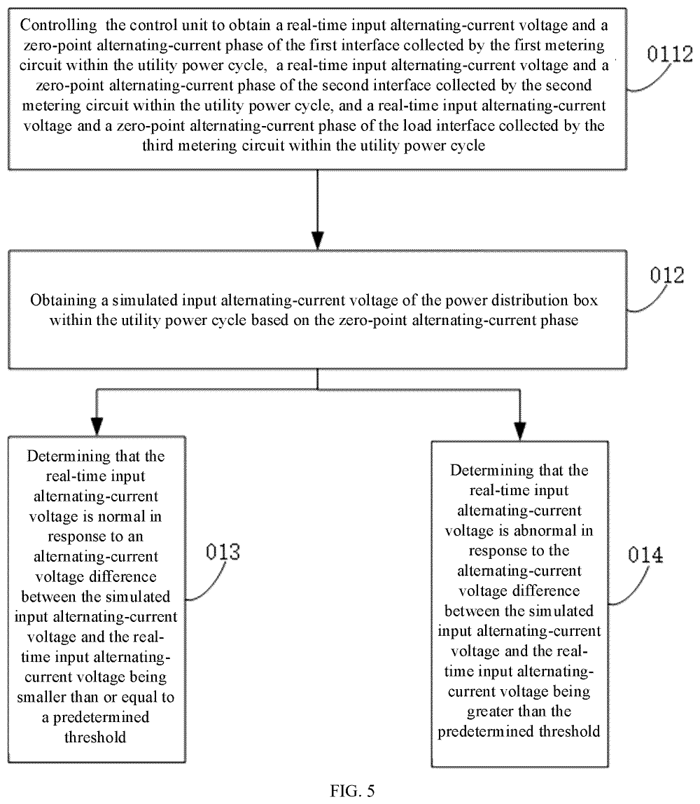

Referring to FIG. 2 and FIG. 5, in some embodiments, the power distribution box 100 includes a first metering circuit 92 electrically connected to the first interface 40, the control unit 80, and the switching switch 60. The operation at block 011 of obtaining the real-time input alternating-current voltage and the zero-point alternating-current phase of the power distribution box 100 within the utility power cycle includes an operation at block 0112.

At block 0112, the control unit 80 is controlled to obtain a real-time input alternating-current voltage and a zero-point alternating-current phase of the first interface 40 collected by the first metering circuit 92 within the utility power cycle.

In this way, by connecting the first metering circuit 92 to the first interface 40, the control unit 80 can determine whether the first interface 40 is powered, thereby pre-determining whether the power failure detection is required to be performed.

In some embodiments, the power distribution box 100 includes a first metering circuit 92. The metering circuit may also be referred to as a conversion circuit or a signal conditioning circuit, primarily functions to perform further processing and conversion on the collected electrical signal, and includes linearization functions such as amplification processing and filtering control, to obtain a better sensor quality and characteristic. The type of the first metering circuit 92 is determined based on the type of a component connected to the first metering circuit 92.

For example, the first metering circuit 92 includes a bridge circuit, an impedance conversion circuit, an oscillation circuit, and the like. The first metering circuit 92 is electrically connected to the first interface 40, the control unit 80, and the switching switch 60. The first metering circuit 92 may be connected to the first interface 40 and the control unit 80, which can collect an alternating-current voltage, current, and isolated phase at the first interface 40. In this way, the processor 21 can determine a power supply at the first interface 40 connected to the load based on the alternating-current voltage and the alternating current collected by the first metering circuit 92.

Referring to FIG. 2 and FIG. 5, in some embodiments, the power distribution box 100 includes a second metering circuit 94 electrically connected to the second interface 50, the control unit 80, and the switching switch 60. The operation at block 011 of obtaining the real-time input alternating-current voltage and the zero-point alternating-current phase of the power distribution box 100 within the utility power cycle includes an operation at block 0112.

At block 0112, the control unit 80 is controlled to obtain a real-time input alternating-current voltage and a zero-point alternating-current phase of the second interface 50 collected by the second metering circuit 94 within the utility power cycle.

In this way, by connecting the second metering circuit 94 to the second interface 50, the control unit 80 can determine whether the second interface 50 is powered, thereby pre-determining whether the power failure detection is required to be performed.

In some embodiments, the power distribution box 100 includes a second metering circuit 94. The metering circuit may also be referred to as a conversion circuit or a signal conditioning circuit, primarily functions to perform further processing and conversion on the collected electrical signal, and includes linearization functions such as amplification processing and filtering control, to obtain a better sensor quality and characteristic. The type of the second metering circuit 94 is determined based on the type of a component connected to the second metering circuit 94.

For example, the second metering circuit 94 includes a bridge circuit, an impedance conversion circuit, an oscillation circuit, and the like. The second metering circuit 94 is electrically connected to the second interface 50, the control unit 80, and the switching switch 60. For example, the second metering circuit 94 may be connected to the second interface 50 and the control unit 80, which can collect an alternating-current voltage, current, and isolated phase at the second interface 50. In this way, the processor 21 can determine a power supply at the second interface 50 connected to the load based on the alternating-current voltage and the alternating current collected by the second metering circuit 94.

Referring to FIG. 2 and FIG. 5, in some embodiments, the power distribution box 100 includes a third metering circuit 96 electrically connected to the load interface 30, the control unit 80, and the switching switch 60. The operation at block 011 of obtaining the real-time input alternating-current voltage and the zero-point alternating-current phase of the power distribution box 100 within the utility power cycle includes an operation at block 0112.

At block 0112, the control unit 80 is controlled to obtain a real-time input alternating-current voltage and a zero-point alternating-current phase of the load interface 30 collected by the third metering circuit 96 within the utility power cycle.

In this way, by connecting the third metering circuit 96 to the load interface 30, the control unit 80 can determine whether the load interface 30 is powered, thereby pre-determining whether the power failure detection is required to be performed.

In some embodiments, the power distribution box 100 includes a third metering circuit 96. The metering circuit may also be referred to as a conversion circuit or a signal conditioning circuit, primarily functions to perform further processing and conversion on the collected electrical signal, and includes linearization functions such as amplification processing and filtering control, to obtain a better sensor quality and characteristic. The type of the third metering circuit 96 is determined based on the type of a component connected to the third metering circuit 96.

For example, the third metering circuit 96 may include a bridge circuit, an impedance conversion circuit, an oscillation circuit, and the like. The third metering circuit 96 is electrically connected to the load interface 30, the control unit 80, and the switching switch 60. For example, the third metering circuit 96 may be connected to the load interface 30 and the control unit 80, which can collect an alternating-current voltage, current, and isolated phase at the load interface 30. In this way, the processor 21 can determine whether the load interface connected to the load is powered based on the alternating-current voltage and the alternating current collected by the third metering circuit 96.

In the embodiments shown in FIG. 2 to FIG. 5, the power distribution box 100 includes a first metering circuit 92, a second metering circuit 94, and a third metering circuit 96.

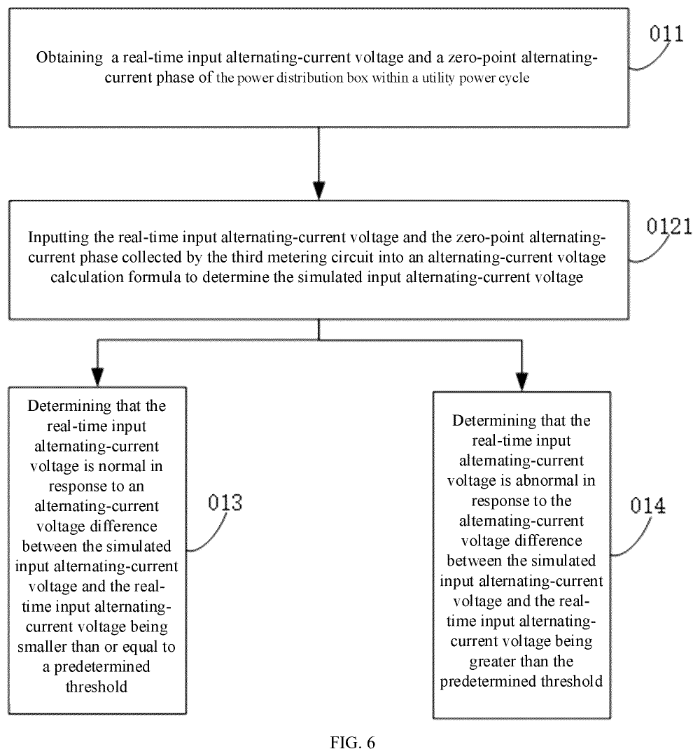

Referring to FIG. 6, in some embodiments, the operation at block 012 of obtaining the simulated input alternating-current voltage of the power distribution box 100 within the utility power cycle based on the zero-point alternating-current phase includes an operation at block 0121.

At block 0121, the real-time input alternating-current voltage and the zero-point alternating-current phase collected by the third metering circuit 96 are inputted into an alternating-current voltage calculation formula to determine the simulated input alternating-current voltage.

In this way, the third metering circuit 96 transmits the collected real-time input alternating-current power supply to the control unit 80, enabling the control unit 80 to calculate a simulated input alternating-current voltage for comparison with the real-time input alternating-current voltage based on the alternating-current voltage calculation formula, thereby determining whether the real-time input alternating-current voltage is abnormal.

In some embodiments, after the control unit 80 obtains the real-time input alternating-current voltage collected by the third metering circuit 96, the simulated input alternating-current voltage can be determined based on the zero-point alternating-current phase collected by the isolated operational amplifier circuit 72 and the alternating-current voltage calculation formula pre-inputted in the control unit 80. The simulated input alternating-current voltage is a theoretical value, which is unaffected by the environmental factor, of a voltage supplied by the utility power supply or the portable energy storage power supply to the load.

For example, the alternating-current voltage calculation formula may be represented as V=Vm*sin(ωt+φ), where t represents time in seconds; v(t) represents a voltage at time t in volts; Vm represents a peak voltage, i.e., an amplitude in volts; ω represents an angular frequency in radians per second, related to a frequency f by ω=2πfω=2πf; and φ represents a phase angle in radians, indicating a phase difference of the voltage with respect to a reference point. Vm, ω, and φ in the alternating-current voltage calculation formula can be determined based on the zero-point alternating-current phase and a plurality of real-time input alternating-current voltages, and thus the simulated input alternating-current voltage can be determined.

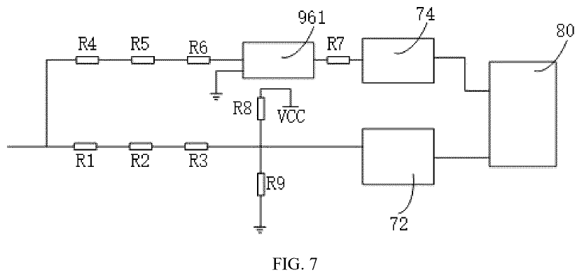

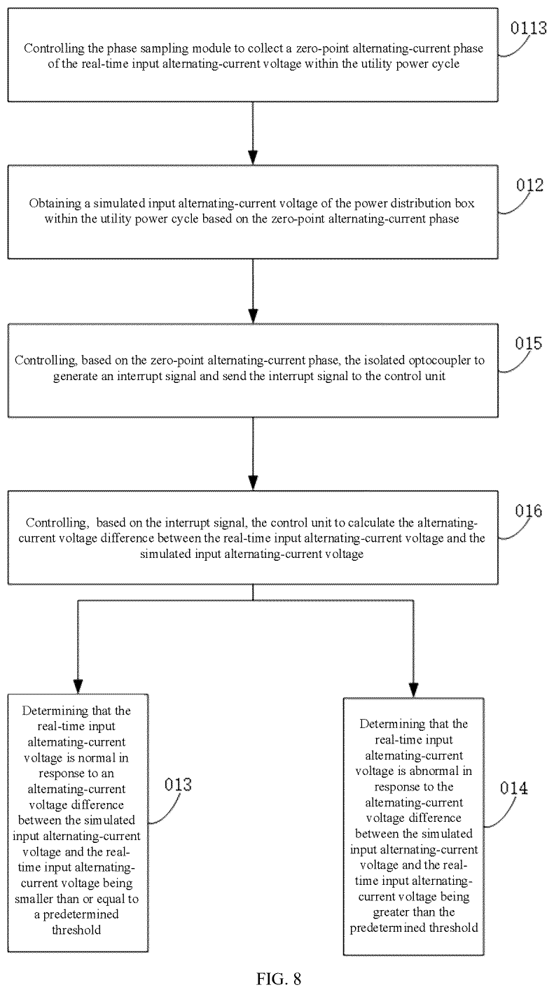

Referring to FIG. 2, FIG. 7, and FIG. 8, in some embodiments, the third metering circuit 96 includes a phase sampling module 961, and the power distribution box 100 further includes an isolated optocoupler 74. The isolated optocoupler 74 is electrically connected to the control unit 80 and the phase sampling module 961, and the phase sampling module 961 is electrically connected to the load interface 30. The operation at block 011 of obtaining the real-time input alternating-current voltage and the zero-point alternating-current phase of the power distribution box 100 within the utility power cycle includes an operation at block 0113.

At block 0113, the phase sampling module 961 is controlled to collect a zero-point alternating-current phase of the real-time input alternating-current voltage within the utility power cycle.

The detection method further includes operations at blocks 015 and 016.

At block 015, the isolated optocoupler 74 is controlled, based on the zero-point alternating-current phase, to generate an interrupt signal and send the interrupt signal to the control unit 80.

At block 016, the control unit 80 is controlled, based on the interrupt signal, to calculate the alternating-current voltage difference between the real-time input alternating-current voltage and the simulated input alternating-current voltage.

In this way, a zero-point phase of the real-time input alternating-current voltage can be precisely collected by providing the phase sampling module 961, and the interrupt signal is generated and sent to the control unit 80 by the isolated optocoupler 74 based on the zero-point alternating-current phase, such that the control unit 80 can align zeroing starting points of the simulated input alternating-current voltage and the real-time input alternating-current voltage, achieving real-time verification of the zero-point alternating-current phase during a change of an alternating-current voltage phase, and ensuring that a voltage waveform of each utility power cycle starts from an alternating-current voltage zero-point.

In some embodiments, the third metering circuit 96 includes a phase sampling module 961, and the power distribution box 100 includes an isolated optocoupler 74. The phase sampling module 961 may be a phase sampling chip, and is capable of being electrically connected to the load interface 30 to accurately collect the zero-point alternating-current phase of the input alternating-current voltage supplied to the load. The isolated optocoupler 74, also known as an optoelectronic isolator or a photoelectric coupler, uses photoelectric conversion devices (such as a luminous diode and a phototransistor) to physically isolate an input signal and an output signal and allow the input signal and the output signal not to interfere with each other. The isolated optocoupler 74 has an end capable of being connected to the control unit 80, and another end capable of being connected to the phase sampling module 961. In this way, the zero-point alternating-current phase collected by the phase sampling module 961 can be transmitted to the isolated optocoupler 74, and the isolated optocoupler 74 can generate the interrupt signal and send the interrupt signal to the control unit 80 based on the zero-point alternating-current phase.

In some embodiments, the control unit 80 is capable of aligning the zeroing starting points of the real-time input alternating-current voltage and the simulated input alternating-current voltage subsequent to receiving the interrupt signal, and then calculating an alternating-current voltage difference between the real-time input alternating-current voltage and the simulated input alternating-current voltage within the same time period.

Therefore, a calculation manner for the alternating-current voltage difference between the real-time input alternating-current voltage and the simulated input alternating-current voltage is simple and has high efficiency.

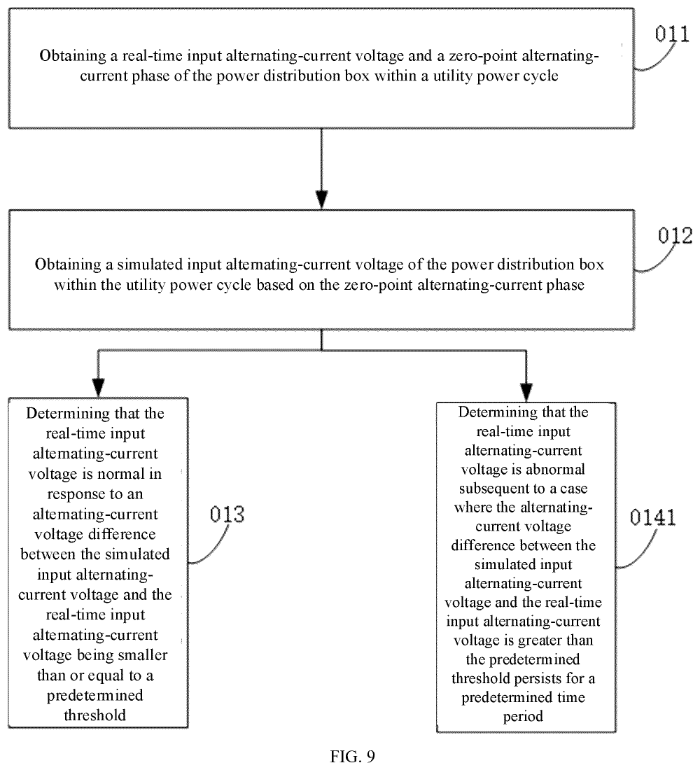

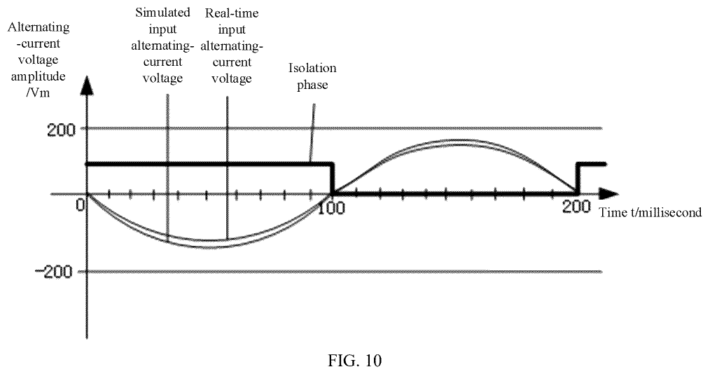

Referring to FIG. 9 and FIG. 10, in some embodiments, the operation at block 014 of determining that the real-time input alternating-current voltage is abnormal in response to the alternating-current voltage difference between the simulated input alternating-current voltage and the real-time input alternating-current voltage being greater than the predetermined threshold includes an operation at block 0141.

At block 0141, it is determined that the real-time input alternating-current voltage is abnormal subsequent to a case where the alternating-current voltage difference between the simulated input alternating-current voltage and the real-time input alternating-current voltage is greater than the predetermined threshold persists for a predetermined time period.

In this way, only by setting that the alternating-current voltage difference is determined to be greater than the predetermined threshold within the predetermined time period, it is determined that the real-time input alternating-current voltage is abnormal, which can avoid false determination caused by an error, and can improve the accuracy of determining the abnormity of the real-time input alternating-current voltage.

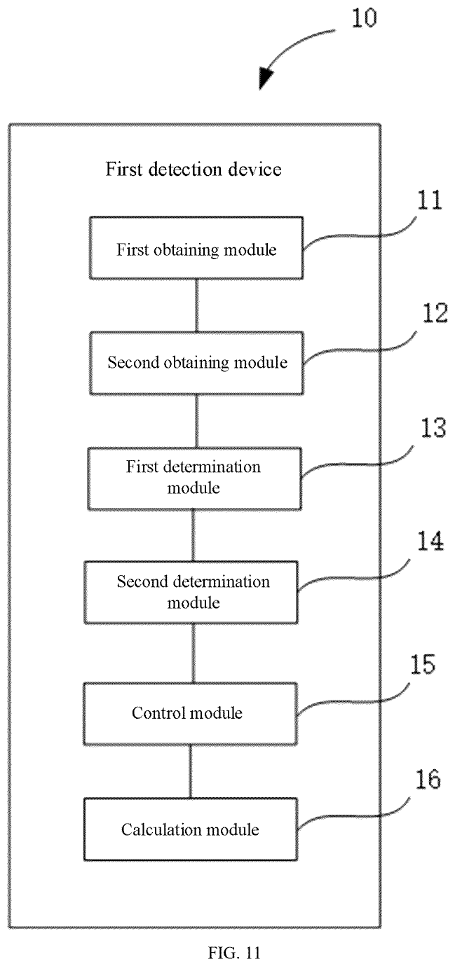

In some embodiments, upon sampling the zero-point alternating-current phase of the input alternating-current voltage, the control unit 80 compares the real-time input alternating-current voltage with the simulated input alternating-current voltage in real time. Since the zero-point alternating-current phase of each utility power cycle is aligned, the false triggering is prevented from occurring in the comparison between the real-time input alternating-current voltage and the simulated input alternating-current voltage due to phase shift of the input alternating-current voltage, which can determine whether trends of the two input alternating-current voltages are synchronized (as shown in FIG. 11). When the processor 21 determines that the trends of the two input alternating-current voltages are synchronized, and in response to the alternating-current voltage difference between the simulated input alternating-current voltage and the real-time input alternating-current voltage being greater than the predetermined threshold within the predetermined time period, it is determined that the real-time input alternating-current voltage is abnormal.

For example, the predetermined time period may be 2 milliseconds, 3 milliseconds, or 4 milliseconds, and the predetermined threshold may be 5 volts, 10 volts, or 20 volts. In this embodiment, as an example, the predetermined time period is 2 milliseconds, and the predetermined threshold is 10 volts. In response to the processor 21 sampling the real-time input alternating-current voltage 10 times within 2 milliseconds, the control unit 80 compares voltages of these 10 real-time input alternating-current voltage samplings with the corresponding simulated input alternating-current voltage to obtain alternating-current voltage differences for these 10 samplings. In response to each of the voltage differences of the 10 samplings within 2 milliseconds being greater than 10 volts, it is determined that the real-time input alternating-current voltage is abnormal.

Referring to FIG. 11, in order to facilitate better implementation of the detection method according to the embodiments of the present disclosure, the embodiments of the present disclosure further provide a first control device 10 applied in the power distribution box 100. The first control device 10 includes a first obtaining module 11, a second obtaining module 12, a first determination module 13, and a second determination module 14. The first obtaining module 11 is configured to obtain a real-time input alternating-current voltage and a zero-point alternating-current phase of the power distribution box 100 within a utility power cycle. The second obtaining module 12 is configured to obtain a simulated input alternating-current voltage of the power distribution box 100 within the utility power cycle based on the zero-point alternating-current phase. The first determination module 13 is configured to determine that the real-time input alternating-current voltage is normal in response to an alternating-current voltage difference between the simulated input alternating-current voltage and the real-time input alternating-current voltage being smaller than or equal to a predetermined threshold. The second determination module 14 is configured to determine that the real-time input alternating-current voltage is abnormal in response to the alternating-current voltage difference between the simulated input alternating-current voltage and the real-time input alternating-current voltage being greater than the predetermined threshold.

The first obtaining module 11 is specifically configured to control the control unit 80 to collect an input alternating-current voltage converted by the isolated operational amplifier circuit 72 to obtain the real-time input alternating-current voltage.

The first obtaining module 11 is specifically configured to control the control unit 80 to obtain a real-time input alternating-current voltage and a zero-point alternating-current phase of the first interface 40 collected by the first metering circuit 92 within the utility power cycle, a real-time input alternating-current voltage and a zero-point alternating-current phase of the second interface 50 collected by the second metering circuit 94 within the utility power cycle, and a real-time input alternating-current voltage and a zero-point alternating-current phase of the load interface 30 collected by the third metering circuit 96 within the utility power cycle.

The second obtaining module 12 is specifically configured to input the real-time input alternating-current voltage and the zero-point alternating-current phase collected by the third metering circuit 96 into an alternating-current voltage calculation formula to determine the simulated input alternating-current voltage.

The first obtaining module 11 is specifically configured to control the phase sampling module 961 to collect a zero-point alternating-current phase of the real-time input alternating-current voltage within the utility power cycle.

In some embodiments, the first control device 10 further includes a control module 15. The control module 15 is configured to control, based on the zero-point alternating-current phase, the isolated optocoupler 74 to generate an interrupt signal and send the interrupt signal to the control unit 80.

In some embodiments, the first control device 10 further includes a calculation module 16. The calculation module 16 is configured to control, based on the interrupt signal, the control unit 80 to calculate an alternating-current voltage difference between the real-time input alternating-current voltage and the simulated input alternating-current voltage.

The second determination module 14 is specifically configured to determine that the real-time input alternating-current voltage is abnormal subsequent to a case where the alternating-current voltage difference between the simulated input alternating-current voltage and the real-time input alternating-current voltage is greater than the predetermined threshold persists for a predetermined time period.

In some embodiments, the first control device 10 may be disposed in the power distribution box 100 to implement functions of the first obtaining module 11, the second obtaining module 12, the first determination module 13, and the second determination module 14 in the power distribution box 100.

In an embodiment, the control unit may include a first control device.

In an embodiment, the control unit may be in a communication connection with the first control device, and the first control device may implement the corresponding steps by controlling the control unit.

The first control device 10 is described above from the perspective of functional modules in conjunction with the accompanying drawings. The functional modules can be implemented in a form of hardware, instructions in a form of software, or a combination of hardware and software modules. In some embodiments, steps of the method embodiments in the embodiments of the present disclosure can be completed by hardware integrated logic circuits in a processor 21 and/or instructions in the form of software. The steps of the method that are disclosed in combination with the embodiments of the present disclosure can be directly embodied as being executed by a hardware decoding processor, or executed by a combination of hardware and software modules in the decoding processor. Optionally, the software module may be located in a mature storage medium in the field such as a random access memory, a flash memory, a Read-Only Memory (ROM), a Programmable ROM (PROM), an electrically erasable programmable memory, a register, etc. The storage medium is located in the memory 22, and the processor 21 reads information from the memory 22, and completes the steps in the above method embodiments in combination with hardware thereof.

Referring to FIG. 12, the second control device 20 according to the embodiments of the present disclosure includes a processor 21, a memory 22, and a computer program 221. The computer program 221 is stored in the memory 22 and executed by the processor 21. The computer program 221 includes an instruction configured to execute the detection method according to any one of the above-described embodiments. For brevity, detailed descriptions thereof are omitted herein.

The power distribution box according to the embodiments of the present disclosure includes a control device, which may be the first control device 10 or the second control device 20.

Referring to FIG. 13, the embodiments of the present disclosure further provide a non-volatile computer-readable storage medium 200 including a computer program 221. The computer program 221, when executed by a processor 21, causes the processor 21 to execute the detection method according to any one of the above-described embodiments. For brevity, detailed descriptions thereof are omitted herein.

In the description of this specification, descriptions with reference to the terms “some embodiments”, “in an example”, “exemplarily” etc., mean that specific features, structures, materials or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner. In addition, those skilled in the art can combine the different embodiments or examples and the features of the different embodiments or examples described in this specification without contradicting each other.

Any process or method described in a flowchart or described herein in other ways may be understood to include one or more modules, segments, or portions of codes of executable instructions for achieving specific logical functions or steps in the process. The scope of a preferred embodiment of the present disclosure includes other implementations. A function may be performed not in a sequence shown or discussed, including a substantially simultaneous manner or a reverse sequence based on the function involved, which should be understood by those skilled in the art to which the embodiments of the present disclosure belong.

Although the embodiments of the present disclosure have been shown and described above, it would be appreciated by those skilled in the art that the above embodiments are optional and cannot be construed to limitation on the present disclosure, and changes, alternatives, modifications, and variations can be made in the embodiments without departing from scope of the present disclosure.

What is claimed is:

1. A detection method, applied in a power distribution box, the method comprising:
obtaining a real-time input alternating-current voltage and a zero-point alternating-current phase of the power distribution box within a utility power cycle;
obtaining a simulated input alternating-current voltage of the power distribution box within the utility power cycle based on the zero-point alternating-current phase; and
determining that the real-time input alternating-current voltage is normal in response to an alternating-current voltage difference between the simulated input alternating-current voltage and the real-time input alternating-current voltage being smaller than or equal to a predetermined threshold, or determining that the real-time input alternating-current voltage is abnormal in response to the alternating-current voltage difference between the simulated input alternating-current voltage and the real-time input alternating-current voltage being greater than the predetermined threshold.

2. The detection method according to claim 1, wherein the power distribution box comprises:
a load interface;
a first interface;
a second interface;
a switching switch configured to switch connections between the load interface and the first interface and between the load interface and the second interface;
an isolated operational amplifier circuit disposed between the load interface and the switching switch; and
a control unit electrically connected to the isolated operational amplifier circuit,
wherein said obtaining the real-time input alternating-current voltage of the power distribution box comprises:
controlling the control unit to collect an input alternating-current voltage converted by the isolated operational amplifier circuit to obtain the real-time input alternating-current voltage.

3. The detection method according to claim 2, wherein:
the power distribution box further comprises a first metering circuit electrically connected to the first interface, the control unit, and the switching switch; and
said obtaining the real-time input alternating-current voltage and the zero-point alternating-current phase of the power distribution box within the utility power cycle comprises:
controlling the control unit to obtain a real-time input alternating-current voltage and a zero-point alternating-current phase of the first interface collected by the first metering circuit within the utility power cycle.

4. The detection method according to claim 2, wherein:
the power distribution box further comprises a second metering circuit electrically connected to the second interface, the control unit, and the switching switch; and
said obtaining the real-time input alternating-current voltage and the zero-point alternating-current phase of the power distribution box within the utility power cycle comprises:
controlling the control unit to obtain a real-time input alternating-current voltage and a zero-point alternating-current phase of the second interface collected by the second metering circuit within the utility power cycle.

5. The detection method according to claim 2, wherein:
the power distribution box further comprises a third metering circuit electrically connected to the load interface, the control unit, and the switching switch; and
said obtaining the real-time input alternating-current voltage and the zero-point alternating-current phase of the power distribution box within the utility power cycle comprises:
controlling the control unit to obtain a real-time input alternating-current voltage and a zero-point alternating-current phase of the load interface collected by the third metering circuit within the utility power cycle.

6. The detection method according to claim 5, wherein said obtaining the simulated input alternating-current voltage of the power distribution box within the utility power cycle based on the zero-point alternating-current phase comprises:
inputting the real-time input alternating-current voltage and the zero-point alternating-current phase collected by the third metering circuit into an alternating-current voltage calculation formula to determine the simulated input alternating-current voltage.

7. The detection method according to claim 5, wherein:
the third metering circuit comprises a phase sampling module, and the power distribution box further comprises an isolated optocoupler, wherein the isolated optocoupler is electrically connected to the control unit and the phase sampling module, and the phase sampling module is electrically connected to the load interface;
said obtaining the real-time input alternating-current voltage and the zero-point alternating-current phase of the power distribution box within the utility power cycle comprises:
controlling the phase sampling module to collect a zero-point alternating-current phase of the real-time input alternating-current voltage within the utility power cycle; and
the method further comprises:
controlling, based on the zero-point alternating-current phase, the isolated optocoupler to generate an interrupt signal and send the interrupt signal to the control unit; and
controlling, based on the interrupt signal, the control unit to calculate the alternating-current voltage difference between the real-time input alternating-current voltage and the simulated input alternating-current voltage.

8. The detection method according to claim 7, further comprising:
controlling the control unit to align zeroing starting points of the real-time input alternating-current voltage and the simulated input alternating-current voltage subsequent to receiving the interrupt signal, and to calculate an alternating-current voltage difference between the real-time input alternating-current voltage and the simulated input alternating-current voltage within the same time period.

9. The detection method according to claim 1, wherein said determining that the real-time input alternating-current voltage is abnormal in response to the alternating-current voltage difference between the simulated input alternating-current voltage and the real-time input alternating-current voltage being greater than the predetermined threshold comprises:
determining that the real-time input alternating-current voltage is abnormal subsequent to a case where the alternating-current voltage difference between the simulated input alternating-current voltage and the real-time input alternating-current voltage is greater than the predetermined threshold persists for a predetermined time period.

10. A second control device, comprising:
a processor;
a memory; and
a computer program stored in the memory and executed by the processor, the computer program comprising an instruction configured to execute a detection method, the detection method applied in a power distribution box, the power distribution box comprising the second control device,
wherein the detection method comprises:
obtaining a real-time input alternating-current voltage and a zero-point alternating-current phase of the power distribution box within a utility power cycle;
obtaining a simulated input alternating-current voltage of the power distribution box within the utility power cycle based on the zero-point alternating-current phase; and
determining that the real-time input alternating-current voltage is normal in response to an alternating-current voltage difference between the simulated input alternating-current voltage and the real-time input alternating-current voltage being smaller than or equal to a predetermined threshold, or determining that the real-time input alternating-current voltage is abnormal in response to the alternating-current voltage difference between the simulated input alternating-current voltage and the real-time input alternating-current voltage being greater than the predetermined threshold.

11. A power distribution box, comprising a control device, the control device being configured to:
obtain a real-time input alternating-current voltage and a zero-point alternating-current phase of the power distribution box within a utility power cycle;
obtain a simulated input alternating-current voltage of the power distribution box within the utility power cycle based on the zero-point alternating-current phase; and
determine that the real-time input alternating-current voltage is normal in response to an alternating-current voltage difference between the simulated input alternating-current voltage and the real-time input alternating-current voltage being smaller than or equal to a predetermined threshold, or determine that the real-time input alternating-current voltage is abnormal in response to the alternating-current voltage difference between the simulated input alternating-current voltage and the real-time input alternating-current voltage being greater than the predetermined threshold.

12. The power distribution box according to claim 11, further comprising:
a load interface;
a first interface;
a second interface;
a switching switch configured to switch connections between the load interface and the first interface and between the load interface and the second interface;
an isolated operational amplifier circuit disposed between the load interface and the switching switch; and
a control unit electrically connected to the isolated operational amplifier circuit,
wherein the control device is further configured to:
control the control unit to collect an input alternating-current voltage converted by the isolated operational amplifier circuit to obtain the real-time input alternating-current voltage.

13. The power distribution box according to claim 12, wherein:
the power distribution box further comprises a first metering circuit electrically connected to the first interface, the control unit, and the switching switch; and
the control device is further configured to:
control the control unit to obtain a real-time input alternating-current voltage and a zero-point alternating-current phase of the first interface collected by the first metering circuit within the utility power cycle.

14. The power distribution box according to claim 12, wherein:
the power distribution box further comprises a second metering circuit electrically connected to the second interface, the control unit, and the switching switch; and
the control device is further configured to:
control the control unit to obtain a real-time input alternating-current voltage and a zero-point alternating-current phase of the second interface collected by the second metering circuit within the utility power cycle.

15. The power distribution box according to claim 12, wherein:
the power distribution box further comprises a third metering circuit electrically connected to the load interface, the control unit, and the switching switch; and
the control device is further configured to:
control the control unit to obtain a real-time input alternating-current voltage and a zero-point alternating-current phase of the load interface collected by the third metering circuit within the utility power cycle.

16. The power distribution box according to claim 15, wherein the control device is further configured to:
input the real-time input alternating-current voltage and the zero-point alternating-current phase collected by the third metering circuit into an alternating-current voltage calculation formula to determine the simulated input alternating-current voltage.

17. The power distribution box according to claim 15, wherein:
the third metering circuit comprises a phase sampling module, and the power distribution box further comprises an isolated optocoupler, wherein the isolated optocoupler is electrically connected to the control unit and the phase sampling module, and the phase sampling module is electrically connected to the load interface; and
the control device is further configured to:
control the phase sampling module to collect a zero-point alternating-current phase of the real-time input alternating-current voltage within the utility power cycle;
control, based on the zero-point alternating-current phase, the isolated optocoupler to generate an interrupt signal and send the interrupt signal to the control unit; and
control, based on the interrupt signal, the control unit to calculate an alternating-current voltage difference between the real-time input alternating-current voltage and the simulated input alternating-current voltage.

18. The power distribution box according to claim 17, wherein the control device is further configured to:
control the control unit to align zeroing starting points of the real-time input alternating-current voltage and the simulated input alternating-current voltage subsequent to receiving the interrupt signal, and to calculate an alternating-current voltage difference between the real-time input alternating-current voltage and the simulated input alternating-current voltage within one time period.

19. The power distribution box according to claim 11, wherein the control device is further configured to:
determine that the real-time input alternating-current voltage is abnormal subsequent to a case where the alternating-current voltage difference between the simulated input alternating-current voltage and the real-time input alternating-current voltage is greater than the predetermined threshold persists for a predetermined time period.

20. A non-volatile computer-readable storage medium comprising a computer program, wherein the computer program, when executed by a processor, causes the processor to execute the detection method according to claim 1.
